(19) United States
(12) Patent Application Publication
(10) Pub. No.: US 2007/0256285 A1
(43) Pub. Date: Nov. 8, 2007

(54) Fastener

(75) Inventor: Ching-Yu Hsu, Taipei City (TW)

Correspondence Address: BACON & THOMAS, PLLC, 625 SLATERS LANE, FOURTH FLOOR, ALEXANDRIA, VA, 22314, US

(73) Assignee: AMA Precision Inc., Taipei (TW)

(21) Appl. No.: 11/797,395

(22) Filed: May 3, 2007

(30) Foreign Application Priority Data
May 8, 2006 (TW) 095116234

(51) Int. Cl. A44B 21/00; H05K 7/20

(52) U.S. Cl. 24/459

(57) ABSTRACT

A fastener requiring less space for the performance of the locking or unlocking action without causing an interference with other surrounding component parts is disclosed to include a locating bar, a first hook member connected to one end of the locating bar, a slide slidably coupled to the locating bar and having a relatively lower portion and a relatively higher portion, a second hook member inserted through the locating bar and the slide in a first direction, and a transverse pin inserted through the second hook member in a second direction and supported on the slide to control locking/unlocking action of the fastener.

### BACKGROUND OF THE INVENTION

1. Field of the Invention

The present invention relates to fasteners and more particularly, to such a fastener, which is practical for use to fasten a heat sink to, for example, a CPU in the mainframe of a computer.

2. Description of Related Art

The motherboard of an electronic product, for example, a computer, has a CPU. During operation of the computer, the CPU generates heat, i.e., the CPU is a heat source. A heat sink is commonly used in a computer to dissipate heat from the CPU.

Conventionally, a fastener is used to secure a heat sink to the CPU on the motherboard of an electronic product. FIGS. 1 and 2 show an application example of a fastener according to the prior art. According to this design, the fastener 91 has a first hook hole 911 at one side, a second hook hole 912 at an opposite side, and a locking lever 92 pivoted to one end 913 of the fastener near the second hook hole 912. The locking lever 92 has a bottom end 921 and a protruding portion 922.

When in use, the fastener 91 is straddled on the heat sink 94, and then the first hook hole 911 is coupled to one retaining block 932 at one side of the base 931 of the CPU 93 and the second hook hole 912 is coupled to the other retaining block 933 at the opposite side of the base 931 of the CPU 93, and then the locking lever 92 is turned from the unlocking position to the locking position to force the protruding portion 922 into friction engagement with the end 913 of the fastener 91 and to further lift the second hook hole 912 relative to the associating retaining block 933, thereby locking the heat sink 94 to the CPU 93. On the contrary, when turning the locking lever 92 in the reversed direction from the locking position to the unlocking position, the second hook hole 912 is loosened from the associating retaining block 933.

In the aforesaid design, the user can turn the locking lever 92 between the locking position and the unlocking position to force the second hook hole 912 into engagement with the associating retaining block 933 or to loosen the second hook hole 912 from the associating retaining block 933, thereby locking the heat sink 94 to the CPU 93, or unlocking the heat sink 94 from the CPU 93.

FIGS. 3 and 4 show an application example of another design of fastener according to the prior art. The fastener of this design is substantially similar to the fastener shown in FIGS. 1 and 2 with the exception that the fastener 95 uses a cam wheel 96 instead of the aforesaid locking lever. The cam wheel 96 has a relatively lower portion 961 and a relatively higher portion 962. When rotating the cam wheel 96 leftwards or rightwards relative to the fastener 95, the locking hole 951 of the fastener 95 is lifted to the locking position or lowered to the unlocking position.

In the aforesaid two prior art designs, an operation space is needed for allowing the user to turn the locking lever 92 or rotate the cam wheel 96 between the locking position and the unlocking position, i.e., the locking lever 92 or the cam wheel 96 requires a large moving space, which may interfere with the installation of other component parts, such as cooling fan or cover member, bringing a barrier to product design.

### SUMMARY OF THE INVENTION

The present invention has been accomplished under to provide a fastener, which eliminates the aforesaid problem. According to the present invention, the fastener comprises a locating bar, a first hook member, a slide, a second hook member, and a transverse pin. The locating bar has a first end. The first hook member is connected to the first end of the locating bar. The slide is coupled to the locating bar and slidable relative to the locating bar, having a relatively lower portion and a relatively higher portion. The second hook member is inserted through the locating bar and the slide in a first direction. The transverse pin is inserted through the second hook member in a second direction and supported on the slide.

Therefore, when sliding the slide on the locating bar in one direction, the transverse pin is slid to the relative lower portion of the slide. On the contrary, when sliding the slide on the locating bar in the reversed direction, the transverse pin is slid to the relative higher portion of the slide, and the second hook member is moved to a relatively higher position. Thus, by means of the aforesaid sliding design, the locating bar can be driven to perform a locking or unlocking action within a limited space and without causing an interference with other component parts. Further, this design is easy to operate, and enables the user to apply a force to the slide conveniently.

Further, the locating bar has a second end opposite to the first end, and a track fixedly provided at the second end. The slide is mounted on and slidable along the track.

Further, the track has a vertical slot; the slide has a through hole extending between the relatively lower portion and the relatively higher portion corresponding to the vertical slot of the track; the second hook member is inserted through the vertical slot of the track and the through hole of the slide to an outside space above the slide.

Further, the second hook member has a stop portion protruded from a middle part thereof, and a hook portion disposed at a bottom side thereof.

The fastener further comprises spring means stopped between the second hook member and the locating bar.

Further, the slide has a wedge face, which has one end to be the relatively lower portion and an opposite end to be the relatively higher portion.

Further, the slide has a locating groove on the relatively higher portion for holding the transverse pin in the relatively higher portion when the transverse pin is slid from the relative lower portion to the relatively higher portion.

### BRIEF DESCRIPTION OF THE DRAWINGS

FIG. 1 is an exploded view of a CPU, a heat sink, and a fastener according to the prior art;

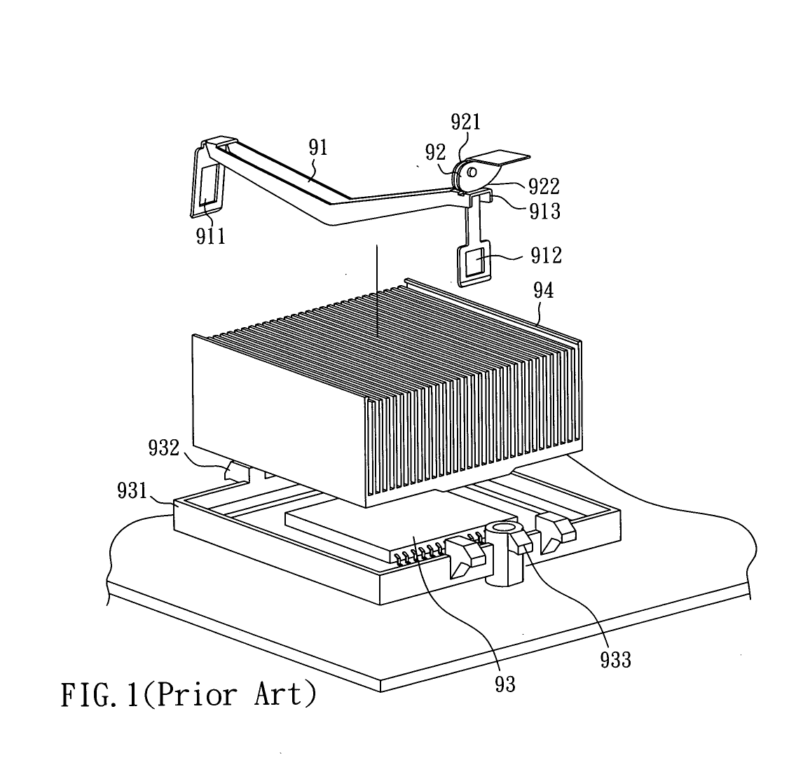

FIG. 2 is a schematic drawing showing the mounting procedure of the assembly of FIG. 1;

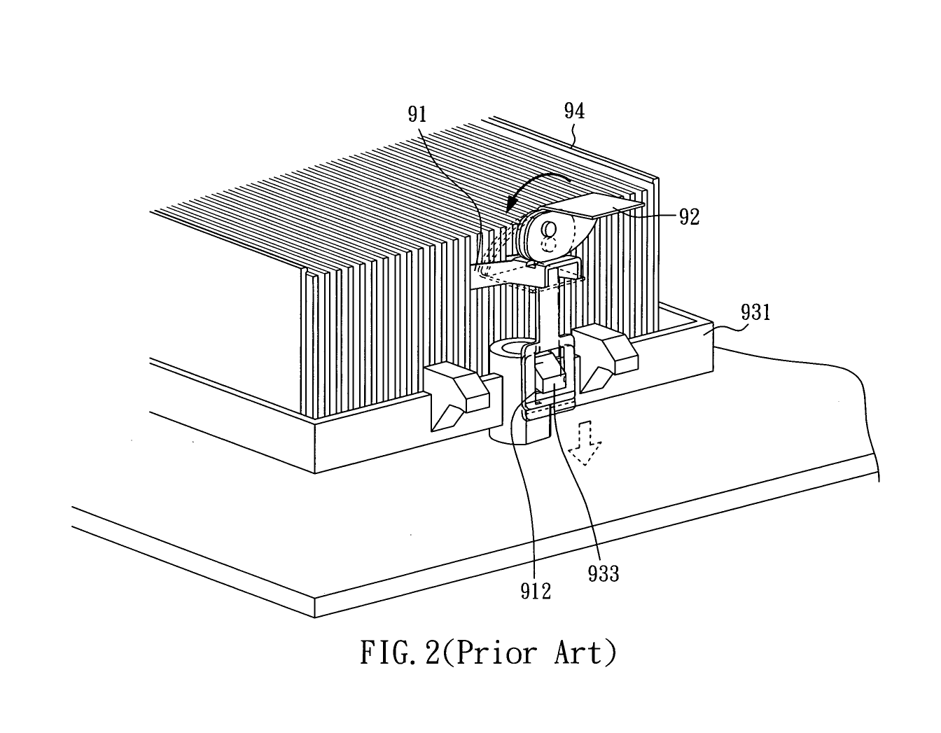

FIG. 3 is an exploded view of a CPU, a heat sink, and another structure of fastener according to the prior art;

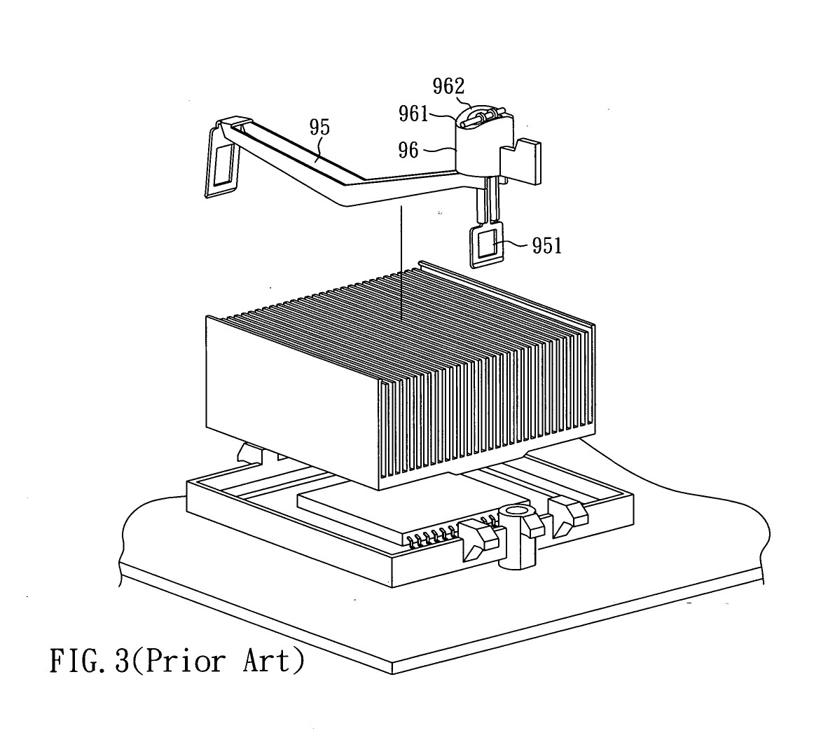

FIG. 4 is a schematic drawing showing the mounting procedure of the assembly of FIG. 3;

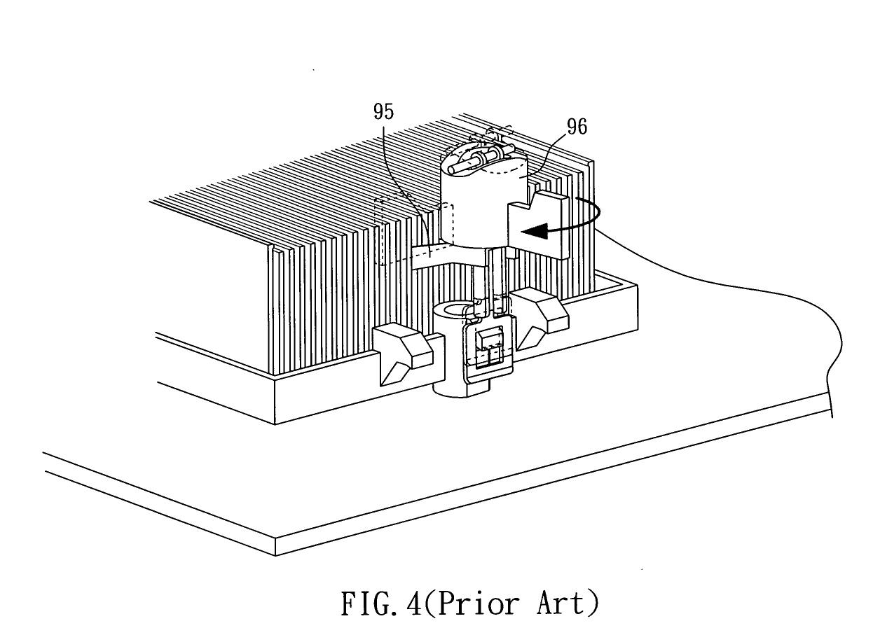

FIG. 5 shows the basic architecture of a fastener in accordance with the present invention;

FIG. 6 is an exploded view of a fastener in accordance with a first embodiment of the present invention;

FIG. 7 is an exploded view of a CPU, a heat sink, and a fastener according to the first embodiment of the present invention;

FIG. 8 is a schematic drawing showing the mounting procedure of the assembly of FIG. 7 (I);

FIG. 9 is a schematic drawing showing the mounting procedure of the assembly of FIG. 7 (II); and

FIG. 10 is an elevational view of a fastener in accordance with a second embodiment of the present invention.

### DETAILED DESCRIPTION OF THE PREFERRED EMBODIMENT

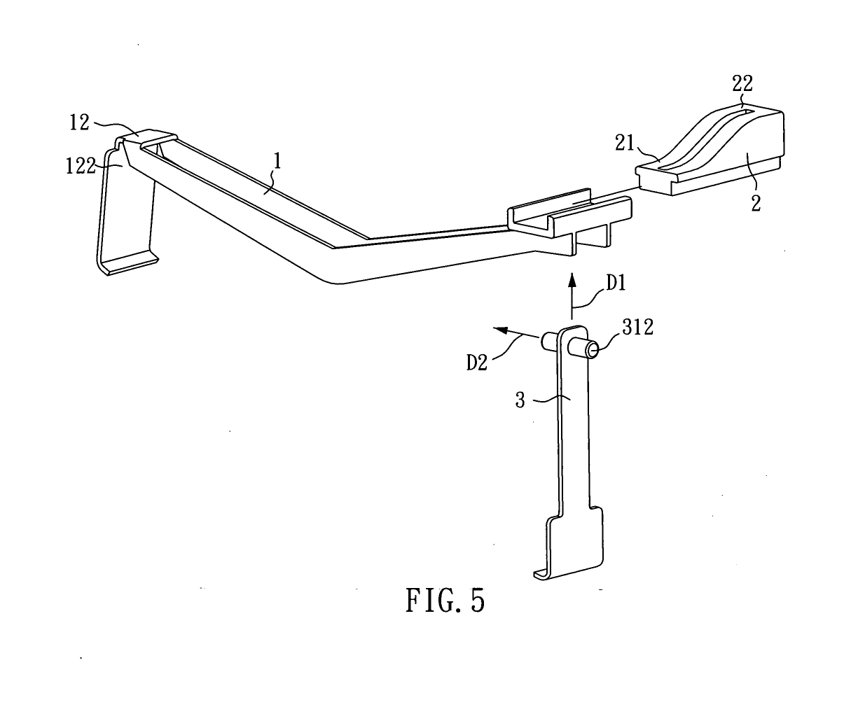

FIG. 5 shows the basic architecture of a fastener in accordance with the present invention. As illustrated, the fastener comprises a locating bar 1, a first hook member 122, a slide 2, a second hook member 3, and a transverse pin 312. The locating bar 1 has a first end 12. The first hook member 122 is connected to the first end 12 of the locating bar 1. The slide 2 is coupled to the locating bar 1 and slidable relative to the locating bar 1, having a relatively lower portion 21 and a relatively higher portion 22. The second hook member 3 is inserted through the locating bar 1 and the slide 2 in a first direction D1. The transverse pin 312 is inserted through the second hook member 3 in a second direction D2, and positioned on the slide 2.

When sliding the slide 2 on the locating bar 1 in one direction, the transverse pin 312 is slid to the relative lower portion 21 of the slide 2. On the contrary, when sliding the slide 2 on the locating bar 1 in the reversed direction, the transverse pin 312 is slid to the relative higher portion 22 of the slide 2, and the second hook member 3 is moved to a relatively higher position.

Thus, by means of the aforesaid sliding design, the locating bar 1 can be driven to perform a locking or unlocking action within a limited space and without causing an interference with other component parts. Further, this design is easy to operate, and enables the user to apply a force to the slide conveniently. Based on the aforesaid basic architecture, the invention may be variously embodied.

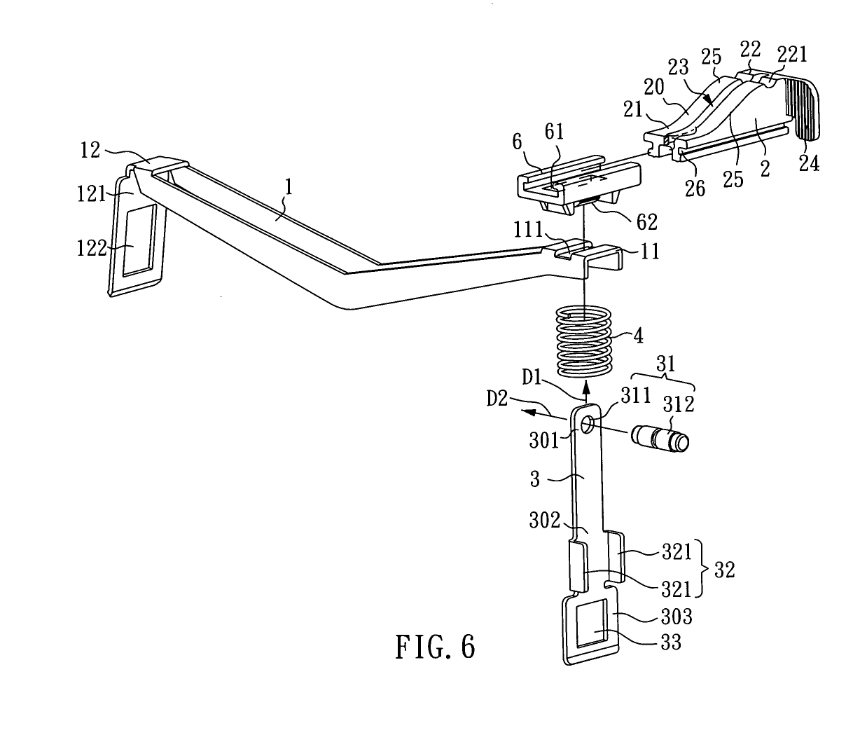

FIG. 6 is an exploded view of a fastener in accordance with a first embodiment of the present invention. As illustrated, the locating bar 1 has a first end 12 and a second end 11 opposite to the first end 12. The second end 11 has a mounting hole 111. The first end 12 has a downwardly extending locating plate 121. A first hook member 122 is provided at the locating plate 121. According to this embodiment, the first hook member 122 is a transverse hook hole facing to the second end 11.

Further, a track 6 is shown fixedly mounted on the top side of the second end 11 of the locating bar 1 in a transverse direction. According to this embodiment, the track 6 has a bottom mounting member 62 fastened to the mounting hole 111 of the locating bar 1, and a vertical slot 61 aimed at one end of the mounting hole 111 of the locating bar 1.

Further, the slide, referenced by 2, is coupled to and slidable along the transversely extending track 6. According to this embodiment, the slide 2 has two sliding grooves 26 arranged on two opposite lateral sides thereof in parallel and coupled to the track 6, which is shaped like a channel bar. Further, in this embodiment, the slide 2 is formed of two sliding plates 25 that have the same shape and are fastened together in a parallel manner. The slide 2 comprises a wedge face 20, a through hole 23, and a push board 24. The wedge face 20 is a non-linear wedge face, having a relatively lower portion 21 at one end and a relatively higher portion 22 at the other end. The through hole 23 cuts through the wedge face 20, and extends from the relatively lower portion 21 to the relatively higher portion 22 corresponding to the vertical slot 61 of the track 6.

As shown in FIG. 6, the second hook member 3 is inserted from the bottom side toward the top side in vertical direction (the first direction D1) through the vertical slot 61 of the track 6 and the through hole 23 of the slide 2 to the outside of the slide 2. The second hook member 3 has a head 31, a stop portion 32, and a hook portion 33. The head 31 is provided at the top side 301 of the second hook member 3 and disposed above the through hole 23 corresponding to the wedge face 20 of the slide 2. The stop portion 32 protrudes from a middle part 302 of the second hook member 3. The hook portion 33 is provided at the bottom side 303 of the second hook member 3.

In this embodiment, the hook portion 33 of the second hook member 3 is a transverse hook hole facing to the transverse hook hole of the first hook member 122 at the first end 12 of the locating bar 1, and the stop portion 32 of the second hook member 3 is comprised of two lugs 321 respectively perpendicularly extended from two opposite lateral sides of the middle part 302 of the second hook member 3 in same direction. Further, the head 31 of the second hook member 3 has a circular hole 311, and a transverse pin 312 inserted through the circular hole 311 (in the second direction D2) and supported on and slidable along the wedge face 20 of the slide 2. The slide 2 further has a locating groove 221 on the relatively higher portion 22. When the transverse pin 312 is slid to the relatively higher portion 22, it is forced into and positioned in the locating groove 221.

Further, a spring 4 is shown sleeved onto the second hook member 3 and stopped between the stop portion 32 of the second hook member 3 and the second end 11 of the locating bar 1 to impart a pressure to the second hook member 3 away from the locating bar 1.

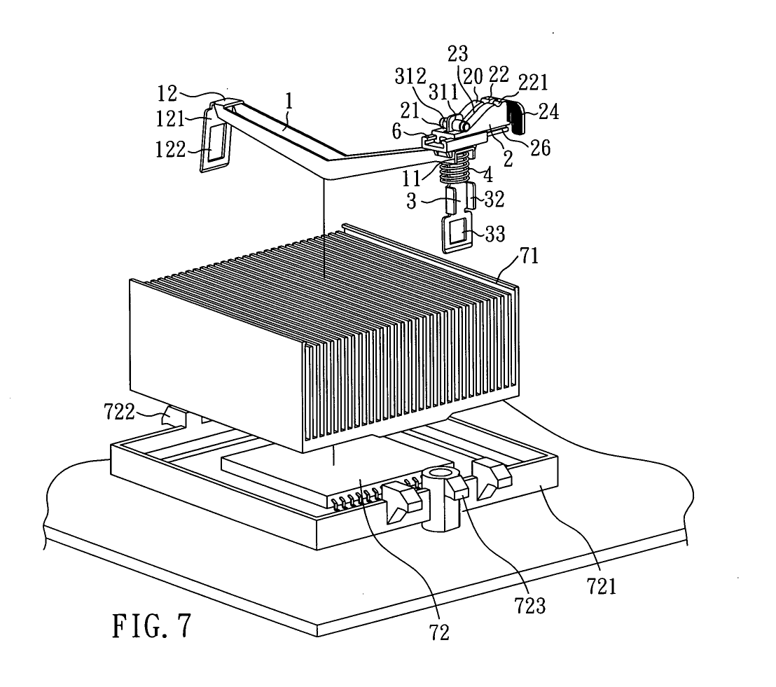

Referring to FIG. 7 and FIG. 6 again, the fastener is used to secure a heat sink 71 to a heat source 72. In this embodiment, the heat sink 71 is formed of radiation fins, and the heat source 72 is a CPU. The heat source 72 has a base 721, and two retaining blocks 722 and 723 symmetrically provided at two opposite sides.

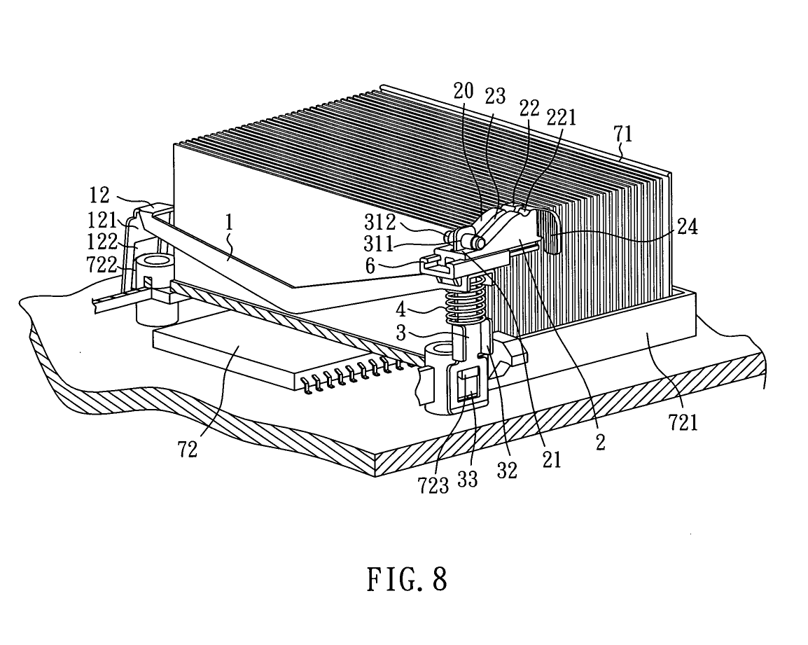

Referring to FIG. 8 and FIGS. 6 and 7 again, when fastening the heat sink 71 to the heat source 72 with the fastener of the present invention, hook the first hook member 122 on the retaining block 722 at one side of the base 721 of the heat source 72 to have the locating bar 1 be straddled on the heat sink 71, and then slide the slide 2 on the track 6 in one direction and have the head 31 of the second hook member 3 be slid along the wedge face 20 of the slide 2 to the relatively lower portion 21 for enabling the spring 4 to push the second hook member 3 downwards. At this time, the heat sink 71 is still not locked to the heat source 72, i.e., the heat sink 71 is in an unlocked status.

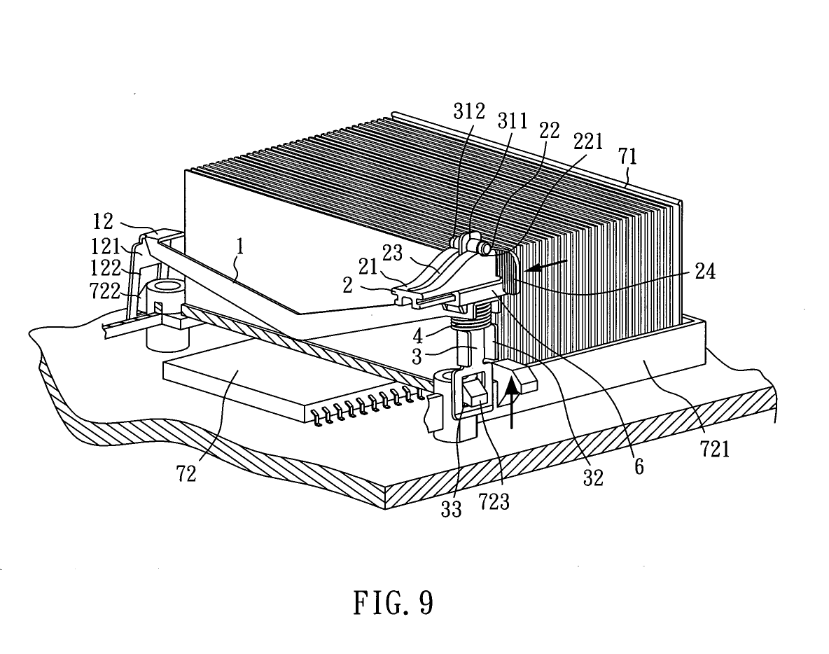

Referring to FIG. 9 and FIGS. 6 and 7 again, after the locating bar 1 has been straddled on the heat sink 71 with the first hook member 122 hooked on the retaining block 722 at one side of the base 721 of the heat source 72, push the push board 24 of the slide 2 to slide the slide 2 on the track 6 in the reversed direction and to have the head 31 of the second hook member 3 be slid along the wedge face 20 of the slide 2 to the relatively higher portion 22 to further compress the spring 4 and lift the second hook member 3 subject to the effect of a cam. Upward displacement of the second hook member 3 at this time causes the hook portion 33 of the second hook member 3 to be forced into engagement with the retaining block 723 at the opposite side of the base 721 firmly (at the same time, the engagement between the first hook member 122 at the locating bar 1 and the retaining block 722 at the base 721 is tightened), thereby locking the heat sink 71 to the heat source 72.

The aforesaid sliding design requires less space for the performance of the locking or unlocking action without causing an interference with other surrounding component parts. Further, this design is easy to operate, and enables the user to apply a force to the slide conveniently.

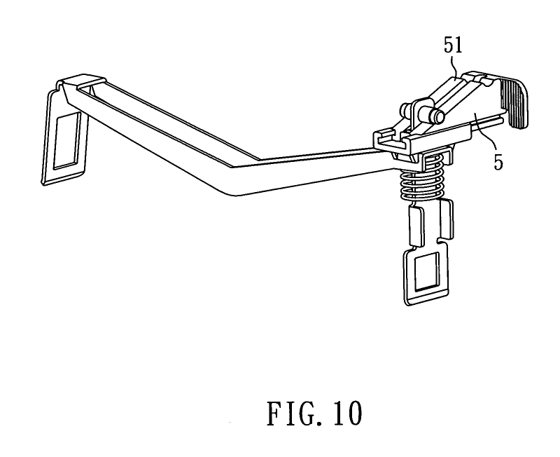

FIG. 10 shows a fastener in accordance with a second embodiment of the present invention. This embodiment is substantially similar to the aforesaid first embodiment with the exception that the wedge face 51 of the slide 5 is a linear wedge face. This second embodiment achieves the same effect as the aforesaid first embodiment of the present invention.

Although the present invention has been explained in relation to its preferred embodiments, it is to be understood that many other possible modifications and variations can be made without departing from the spirit and scope of the invention as hereinafter claimed.

What is claimed is:

1. A fastener comprising:
a locating bar, said locating bar having a first end;
a first hook member connected to the first end of said locating bar;
a slide coupled to said locating bar and slidable relative to said locating bar, said slide having a relatively lower portion and a relatively higher portion;
a second hook member inserted through said locating bar and said slide in a first direction; and
a transverse pin inserted through said second hook member in a second direction and supported on said slide.

2. The fastener as claimed in claim 1, wherein said locating bar further has a second end opposite to said first end, and a track fixedly provided at said second end, said slide is mounted on and slidable along said track.

3. The fastener as claimed in claim 2, wherein said track has a vertical slot, said slide has a through hole extending between said relatively lower portion and said relatively higher portion corresponding to said vertical slot of said track, said second hook member is inserted through the vertical slot of said track and the through hole of said slide to an outside space above said slide.

4. The fastener as claimed in claim 2, wherein the second end of said locating bar has a mounting hole, said track has a bottom mounting member fastened to the mounting hole of said locating bar.

5. The fastener as claimed in claim 1, wherein said second hook member has a stop portion protruded from a middle part thereof, and a hook portion disposed at a bottom side thereof.

6. The fastener as claimed in claim 5, wherein the hook portion of said second hook member is a transverse hook hole.

7. The fastener as claimed in claim 1, further comprising spring means stopped between said second hook member and said locating bar.

8. The fastener as claimed in claim 1, wherein said slide has a wedge face, said wedge face having one end to be said relatively lower portion and an opposite end to be said relatively higher portion.

9. The fastener as claimed in claim 1, wherein said second hook member has a circular hole, said transverse pin is inserted through said circular hole.

10. The fastener as claimed in claim 1, wherein said slide has a locating groove on said relatively higher portion for holding said transverse pin in said relatively higher portion when said transverse pin is slid from said relative lower portion to said relatively higher portion.

11. The fastener as claimed in claim 1, wherein said slide has a push board.

12. The fastener as claimed in claim 1, wherein said first hook member is a transverse hook hole.
